(19) United States
(12) Patent Application Publication
(10) Pub. No.: US 2008/0296768 A1
(43) Pub. Date: Dec. 4, 2008

(54) Copper nucleation in interconnects having ruthenium layers

(76) Inventors: Ramanan V. Chebiam, Hillsboro, OR (US); Valery M. Dubin, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/639,636

(22) Filed: Dec. 14, 2006

(51) Int. Cl. H01L 29/40; H01L 21/44

(52) U.S. Cl. 257/751; 438/687; 438/675; 438/650; 257/762; 257/769

(57) ABSTRACT

A method for fabrication a metal interconnect that includes a ruthenium layer and minimizes void formation comprises forming a barrier layer on a substrate having a trench, depositing a ruthenium layer on the barrier layer, depositing an alloy-seed layer on the ruthenium layer, using an electroless plating process to deposit a copper seed layer on the alloy-seed layer, and using an electroplating process to deposit a bulk metal layer on the copper seed layer. The alloy-seed layer inhibits void formation issues at the ruthenium-copper interface and improves electromigration issues. The electroless copper seed layer inhibits the alloy-seed layer from dissolving into the electroplating bath and reduces electrical resistance across the substrate during the electroplating process.

### BACKGROUND

In the manufacture of integrated circuits, copper interconnects are generally formed on a semiconductor substrate using a copper dual damascene process. Such a process begins with a trench being etched into a dielectric layer and filled with a barrier layer, an adhesion layer, and a seed layer. A physical vapor deposition (PVD) process, such as a sputtering process, may be used to deposit a metal barrier layer (e.g., tantalum nitride) and a ruthenium (Ru) adhesion layer, the combination of which is also known as a TaN/Ru stack, into the trench. The TaN barrier layer prevents copper from diffusing into the underlying dielectric layer. The Ru adhesion layer is required because the subsequently deposited metals do not readily nucleate on the barrier layer which can get oxidized easily. This may be followed by an electroplating process used to deposit a bulk copper layer directly on the Ru adhesion layer to fill the trench and form the interconnect.

Unfortunately, it has been shown that interface voiding issues arise when a copper electroplating process is performed directly on the Ru adhesion layer. In some instances, this interface voiding issue may be avoided by first depositing a copper alloy seed layer over the Ru adhesion layer. Immersing the Cu alloy seed layer into an electroplating bath, however, tends to cause process issues as dissolution of the alloy seed layer occurs and the alloying element then accumulates in the plating bath. In addition, the relatively small grain size of the alloy seed induces a small grain size in the bulk copper metal deposited by the electroplating process, thereby increasing the electrical resistance of the deposited copper. Finally, the relatively high electrical resistance of the alloy seed layer leads to uniformity and gap-fill issues when a current is applied during the electroplating process. Accordingly, alternative techniques for improving the nucleation of copper metal on a ruthenium adhesion layer are needed.

### BRIEF DESCRIPTION OF THE DRAWINGS

FIG. 1 is a process for fabricating a metal interconnect in accordance with an implementation of the invention.

FIGS. 2A through 2F illustrate structures that are formed when the process of FIG. 1 is carried out.

### DETAILED DESCRIPTION

Described herein are systems and methods of forming a more reliable copper interconnect on a ruthenium adhesion layer. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

In accordance with implementations of the invention, a novel electroless copper seed layer is fabricated between an alloy seed layer and a bulk copper layer within a copper interconnect that may be used in integrated circuit applications. The addition of the electroless copper seed layer improves a subsequent copper electroplating process by inhibiting alloy seed dissolution when the alloy seed layer is immersed into the electroplating bath. The electroless copper seed layer also improves nucleation of the bulk copper layer, thereby permitting a bulk copper layer to be formed over a ruthenium layer with a reduced likelihood of void formation and a larger grain size.

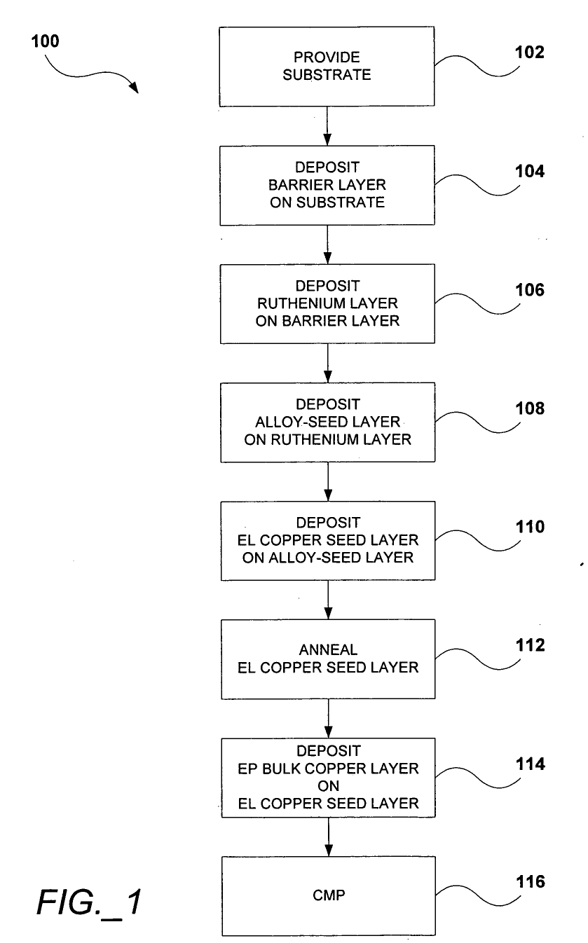

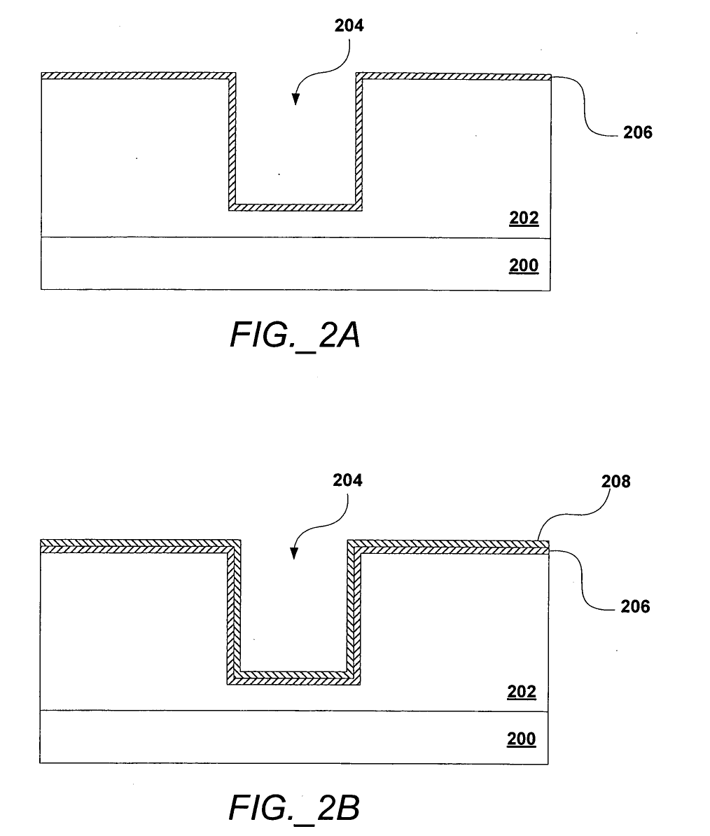

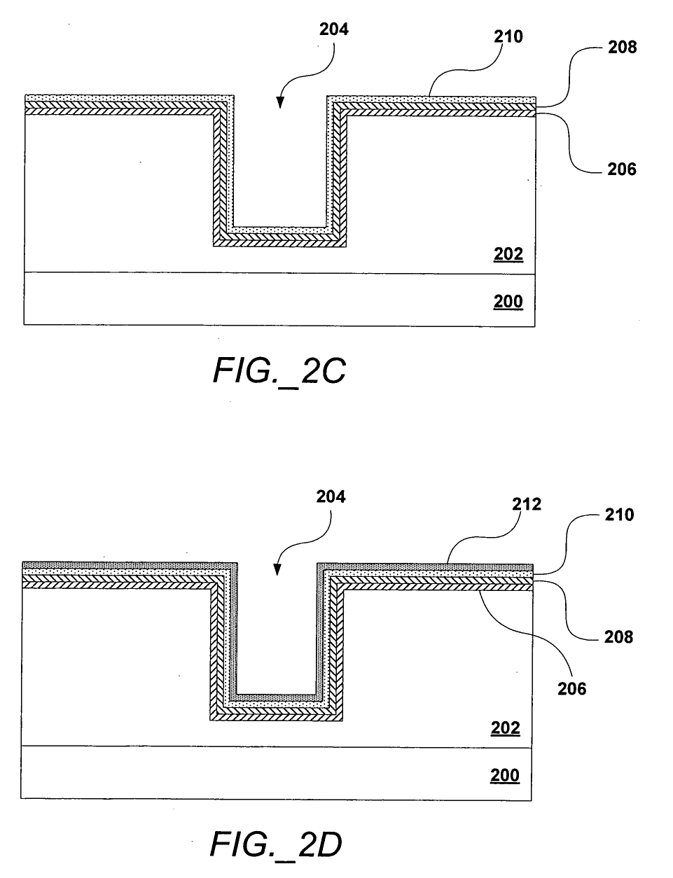

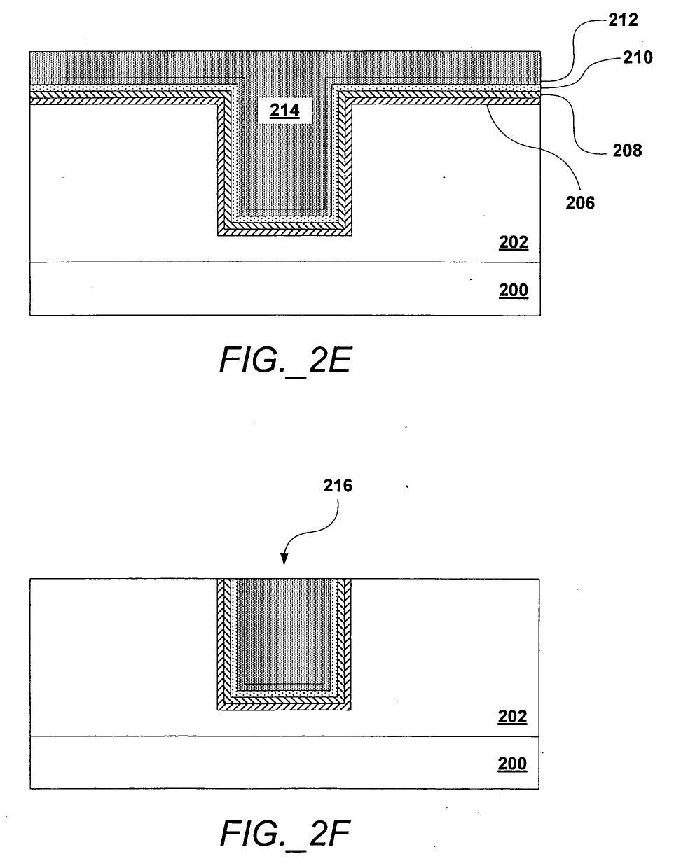

FIG. 1 is a process 100 for fabricating a metal interconnect, such as a copper interconnect, in accordance with an implementation of the invention. FIGS. 2A through 2F illustrate structures that are formed when the process 100 is carried out.

First, a semiconductor substrate is provided upon which the metal interconnect may be formed (process 102 of FIG. 1). The semiconductor substrate may be formed using a bulk silicon or a silicon-on-insulator substructure. In other implementations, the substrate may be formed using alternate materials, which may or may not be combined with silicon, that include but are not limited to germanium, indium antimonide, lead telluride, indium arsenide, indium phosphide, gallium arsenide, gallium antimonide, or other Group III-V materials. Although a few examples of materials from which the semiconductor substrate may be formed are described here, any material that may serve as a foundation upon which a semiconductor device may be built falls within the spirit and scope of the present invention.

The substrate has at least one dielectric layer deposited on its surface. The dielectric layer may be formed using materials known for the applicability in dielectric layers for integrated circuit structures, such as low-k dielectric materials. Such dielectric materials include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The dielectric layer may include pores or other voids to further reduce its dielectric constant. The dielectric layer may include one or more trenches and/or vias within which the cobalt-containing layer will be deposited and the metal interconnect will be formed. The trenches and/or vias may be patterned using conventional wet or dry etch techniques that are known in the art.

The substrate may be housed in a reactor in preparation for a deposition process. In various implementations, the substrate may be heated within the reactor to a temperature between around 50° C. and around 400° C. and the reactor may be heated to a temperature that ranges from 50° C. to 400° C. The pressure within the reactor may range from 0.05 Torr to 3.0 Torr.

A barrier layer is then deposited on the dielectric layer and within the trench (104). The barrier layer may be formed from a material that is known in the art for providing barrier layer functionality, in other words, a material that will substantially inhibit metal from diffusing into the underlying dielectric layer. For instance, if the subsequently formed metal interconnect is a copper interconnect, the barrier layer inhibits copper metal from diffusing into the dielectric layer. In some implementations of the invention, the barrier layer may be formed from tantalum nitride. In other implementations of the invention, alternate materials may be used such as titanium nitride, other metal nitrides, or other metals, including but not limited to tantalum, tungsten, tungsten carbide, tungsten nitride, tantalum silicon nitride, titanium nitride, titanium silicon nitride, ruthenium tantalum, tungsten silicon nitride, ruthenium, and their alloys. In implementations of the invention, the barrier layer may be formed using a deposition process, including but not limited to a physical vapor deposition (PVD) process such as a sputtering process, a chemical vapor deposition (CVD) process, an atomic layer deposition (ALD) process, or a derivative of one of these processes. The barrier layer may be around 3 Angstroms (Å) to 20 nanometers (nm) thick, although it is generally around 10 nm thick.

FIG. 2A illustrates a semiconductor substrate 200 that includes a dielectric layer 202 formed on a top surface of the substrate 200. A trench 204 is formed in the dielectric layer 202. A barrier layer 206, such as a tantalum nitride layer, is formed on the dielectric layer 202 and within the trench 204. As shown, the barrier layer 206 covers the sidewalls and the bottom surface of the trench 204.

Next, a ruthenium layer is formed atop the barrier layer (106). The ruthenium layer is a low resistive layer (relative to most barrier layers) that provides adhesion layer functionality. In other words, the ruthenium layer provides a surface upon which metal may nucleate, thereby enabling a metal such as copper to become deposited over the barrier layer. In some implementations, the ruthenium layer may be formed using a deposition process such as PVD, CVD, ALD, electroless plating (EL), or electroplating (EP). In some implementations, a metal immobilization process (MIP) may be used to form the ruthenium layer. As is known in the art, in a MIP process, a coupling agent such as an azo-silyl moiety may be used to attach the ruthenium metal to the barrier layer. In various implementations, the ruthenium layer may range from 1 nm to 20 nm in thickness.

FIG. 2B illustrates a ruthenium layer 208 that has been deposited over the barrier layer 206. As shown, the ruthenium layer 208 covers the barrier layer 206 both on the surface of the dielectric layer 202 and on the sidewalls and bottom of the trench 204.

As noted above, nucleation issues may arise when a metal, such as copper, is electroplated directly onto the ruthenium layer. This may lead to void formation at the copper-ruthenium interface. To address this issue, an alloy-seed layer may be deposited atop the ruthenium layer (108). A PVD process, such as a sputtering process, may be used to deposit the alloy-seed layer. In alternate implementations, other deposition processes may be used to form the alloy-seed layer, including but not limited to a CVD process and an ALD process.

In some implementations, the alloy-seed layer may consist of a copper and aluminum alloy. In other implementations, alternate metals may be used in the alloy-seed layer, including but not limited to metals such as copper, aluminum, tungsten, tantalum, titanium, silver, cobalt, tin, bismuth, nickel, zinc, palladium, platinum, rhenium, ruthenium, gold, boron, berillium, magnesium, manganese, and calcium. The alloy-seed layer tends to improve the nucleation of metal, thereby inhibiting void formation when a metal such as copper is deposited over the ruthenium layer. The alloy-seed layer also tends to improve electromigration issues with the subsequently deposited metal interconnect. In various implementations, the alloy-seed layer may range up to 20 nm in thickness.

FIG. 2C illustrates an alloy-seed layer 210 that has been deposited over the ruthenium layer 208. As shown, similar to the ruthenium layer 208, the alloy-seed layer 210 covers the ruthenium layer 208 both on the surface of the dielectric layer 202 and on the sidewalls and bottom of the trench 204.

Although the alloy-seed layer helps with electromigration and nucleation issues, the alloy-seed layer also introduces a new set of problems. One problem is that if an electroplating process is now used to fill the trench with copper, the alloy-seed layer may partially dissolve and metal may accumulate in the electroplating bath, thereby negatively impacting the electroplating process. Another problem is that the alloy-seed layer has a relatively small grain size, which imparts a small grain size to a bulk copper layer that nucleates on the alloy-seed layer during the electroplating process. Finally, because the alloy-seed layer has a high electrical resistance relative to pure copper, there may be uniformity and gapfill issues during the electroplating process because the current may not be evenly applied across the substrate.

To address these issues, and in accordance with implementations of the invention, a copper seed layer is deposited over the alloy-seed layer using an electroless (EL) plating process (110). As is well known in the art, an electroless deposition process is a metal deposition process in which the metal begins in solution and a controlled chemical reduction reaction is used to deposit the metal onto a substrate. The electroless process is autocatalytic as the metal being deposited catalyzes the chemical reduction reaction without the need for an external electric current. Electroless plating is a selective deposition and occurs at activated locations on the substrate surface, i.e., locations that have a nucleation potential for an electroless plating solution. Here, the alloy-seed layer provides the activated location upon which the metal may deposit.

The EL copper seed layer reduces the dissolution of metal when the alloy-seed layer is immersed into an electroplating bath. The EL copper seed layer also has lower electrical resistance than the alloy-seed layer, thereby improving uniformity and gapfill during an electroplating process to fill the trench with copper. Furthermore, the EL copper seed layer is known to reduce the native oxide on the seed, thereby increasing the seed margin and improving coverage on the trench sidewalls. Finally, the electromigration benefits provided by the alloy-seed layer are not negatively impacted by the inclusion of the EL copper seed layer, and in fact, in some cases the electromigration performance may actually be improved. This may be due to the fact that the EL copper seed layer has the same <111> orientation as an electroplated bulk copper layer. In various implementations, the EL copper seed layer may range from 1 nm to 50 nm in thickness.

In some implementations, an annealing process may be carried out to modify the EL copper seed layer (112). The annealing process may take place at a temperature that ranges from around 100° C. to 400° C. for a time period that ranges from 10 seconds to 1 hour. The annealing process causes larger grains to form in the EL copper seed layer. As will be appreciated by those of skill in the art, when a bulk copper layer nucleates on the modified EL copper seed layer, the larger grains of the EL copper seed layer enable larger grains to be formed in the bulk copper layer, thereby decreasing the electrical resistance of the bulk copper layer.

FIG. 2D illustrates an EL copper seed layer 212 that has been deposited over the alloy-seed layer 210. As shown, the EL copper seed layer 212 covers the alloy-seed layer 210 both on the surface of the dielectric layer 202 and on the sidewalls and bottom of the trench 204.

Next, a bulk metal layer is deposited atop the EL copper seed layer to fill the trench with metal and form the metal interconnect (114). In most implementations, the bulk metal layer is formed of copper metal or a copper alloy. In alternate implementations, other metals such as aluminum may be used. The bulk metal layer is deposited using an electroplating (EP) process. As is well known in the art, in an electroplating process, a metal layer is deposited on a semiconductor substrate by putting a negative bias on the substrate and immersing it into an electrolyte solution that contains a salt of the metal to be deposited. The electrolyte solution is referred to as a plating bath or an electroplating bath. The metallic ions of the salt carry a positive charge and are attracted to the substrate. When the ions reach the substrate, the negatively charged substrate provides the electrons to “reduce” the positively charged ions to metallic form, thereby causing the metal to deposit on the substrate. The EL copper seed layer provides an area of attachment for the metal ions.

FIG. 2E illustrates a bulk copper layer 214 that has been deposited over the EL copper seed layer 212. As shown, the bulk copper layer 214 fills the trench 204 and covers the EL copper seed layer 212.

Finally, a chemical mechanical polishing (CMP) process may be used to planarize the deposited layers and remove any excess metal to complete fabrication of the metal interconnect (116). The CMP process removes portions of the bulk copper layer, the EL copper seed layer, the alloy-seed layer, the ruthenium layer, and the barrier layer that are sited outside of the trench. CMP is well known in the art and generally involves the use of a rotating polishing pad and an abrasive, corrosive slurry on a semiconductor wafer. After the copper metal is deposited on the surface of a semiconductor wafer, the polishing pad and the slurry physically grind flat the microscopic topographic features until the metal is planarized, thereby allowing subsequent processes to begin on a flat surface. CMP is used in dual damascene processes for producing final copper interconnects on a wafer. CMP slurries used for copper typically contain abrasive particles such as silicon dioxide (SiO₂), aluminum oxide (Al₂O₃), or cerium oxide (CeO₂). CMP slurries for copper also tend to include an oxidizer species such as hydrogen peroxide (H₂O₂), organic complexing agents, surfactants with both hydrophobic and hydrophilic chemical groups, and/or corrosion inhibitors such as benzotriazole.

FIG. 2F illustrates the final copper interconnect 216 after the bulk copper layer 214 has been planarized using a CMP process. As shown, the CMP process has removed portions of the bulk copper layer 214, the EL copper seed layer 212, the alloy-seed layer 210, the ruthenium layer 208, and the barrier layer 206 that are sited outside of the trench 204.

Accordingly, implementations of the invention have been disclosed that enable the fabrication of metal interconnects, such as copper interconnects, that incorporate ruthenium layers while inhibiting issues such as void formation and metal dissolution into an electroplating bath. The disclosed implementations also improve electromigration issues, deposition uniformity, and gapfill. The incorporation of an EL copper seed layer over an alloy-seed layer therefore enables ruthenium layers to be used in metal interconnects while circumventing some of the problems typically associated with these layers.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
depositing a barrier layer on a substrate having a trench;
depositing a ruthenium layer on the barrier layer;
depositing an alloy-seed layer on the ruthenium layer;
using an electroless plating process to deposit a copper seed layer on the alloy-seed layer; and
using an electroplating process to deposit a bulk metal layer on the copper seed layer.

2. The method of claim 1, wherein the barrier layer is deposited using a PVD process.

3. The method of claim 1, wherein the barrier layer comprises at least one of tantalum nitride, titanium nitride, other metal nitrides, or other metals, including but not limited to tantalum, tungsten, tungsten carbide, tungsten nitride, tantalum silicon nitride, titanium nitride, titanium silicon nitride, ruthenium tantalum, tungsten silicon nitride, or ruthenium.

4. The method of claim 1, wherein the ruthenium layer is deposited using one of a PVD process, a CVD process, an ALD process, an electroless plating process, an electroplating process, or a MIP process.

5. The method of claim 1, wherein the alloy-seed layer comprises at least one metal selected from the group consisting of copper, aluminum, tungsten, tantalum, titanium, silver, cobalt, tin, bismuth, nickel, zinc, palladium, platinum, rhenium, ruthenium, gold, boron, berillium, magnesium, manganese, and calcium.

6. The method of claim 1, wherein the alloy-seed layer is deposited using a PVD process, a CVD process, or an ALD process.

7. The method of claim 1, further comprising annealing the copper seed layer prior to using an electroplating process to deposit the bulk metal layer.

8. The method of claim 7, wherein the annealing process takes place at a temperature between around 100° C. and around 400° C. for a time period between around 10 seconds and around 1 hour.

9. The method of claim 1, further comprising planarizing the deposited layers to complete fabrication of a metal interconnect.

10. The method of claim 1, wherein the bulk metal layer comprises copper.

11. An apparatus comprising:
a dielectric layer having a trench that is formed on a substrate;
a barrier layer formed on the dielectric layer within the trench;
a ruthenium layer formed in the barrier layer within the trench;
an alloy-seed layer formed on the ruthenium layer within the trench;
an EL copper seed layer formed on the alloy-seed layer within the trench; and
an EP bulk copper layer formed on the EL copper seed layer within the trench.

12. The apparatus of claim 11, wherein the dielectric layer comprises at least one of the following materials: silicon dioxide, carbon doped oxide, silicon nitride, organic perfluorocyclobutane, polytetrafluoroethylene, fluorosilicate glass, and organosilicates such as silsesquioxane, siloxane, or organosilicate glass.

13. The apparatus of claim 11, wherein the barrier layer comprises at least one of tantalum nitride, titanium nitride, other metal nitrides, or other metals, including but not limited to tantalum, tungsten, tungsten carbide, tungsten nitride, tantalum silicon nitride, titanium nitride, titanium silicon nitride, ruthenium tantalum, tungsten silicon nitride, or ruthenium.

14. The apparatus of claim 11, wherein the barrier layer has a thickness that ranges from 3 Å to 20 nm.

15. The apparatus of claim 11, wherein the ruthenium layer has a thickness that ranges from 1 nm to 20 nm.

16. The apparatus of claim 11, wherein the alloy-seed layer comprises at least one metal selected from the group consisting of copper, aluminum, tungsten, tantalum, titanium, silver, cobalt, tin, bismuth, nickel, zinc, palladium, platinum, rhenium, ruthenium, gold, boron, berillium, magnesium, manganese, and calcium.

17. The apparatus of claim 11, wherein the alloy-seed layer has a thickness that ranges up to 20 nm.

18. The apparatus of claim 11, wherein the EL copper seed layer has a thickness that ranges from 1 nm to 50 nm.

19. The apparatus of claim 11, wherein the substrate comprises at least on of the following materials: silicon, germanium, indium antimonide, lead telluride, indium arsenide, indium phosphide, gallium arsenide, gallium antimonide, and other Group III-V materials.
